(19) United States
(12) Patent Application Publication
(10) Pub. No.: US 2017/0264087 A1
(43) Pub. Date: Sep. 14, 2017

(54) METHOD OF EXPOSING A GLASS-COATED MICROWIRE AND USES THEREOF

(71) Applicants: Elchai BEN-SHUSHAN, Tel Aviv (IL); Zvi Iheskel LINKOVSKI, Tel Aviv (IL); Mark GELLER, Netanya (IL); Shlomo ZUCKER, Michmoret (IL)

(72) Inventors: Elchai BEN-SHUSHAN, Tel Aviv (IL); Zvi Iheskel LINKOVSKI, Tel Aviv (IL); Mark GELLER, Netanya (IL); Shlomo ZUCKER, Michmoret (IL)

(21) Appl. No.: 15/529,379

(22) PCT Filed: Nov. 26, 2015
(86) PCT No.: PCT/IL15/51151

§ 371 Date: May 24, 2017

Related U.S. Application Data
(60) Provisional application No. 62/084,577, filed on Nov. 26, 2014.

(51) Int. Cl. H02G 1/12; H01L 23/00; H01B 13/32; H01L 23/29

(52) U.S. Cl. CPC H02G 1/12; H01L 23/29; H01L 24/42; H01L 24/43; H01B 13/32

(57) ABSTRACT

A method for exposing a microwire from it glass coating in a glass coated microwire. The method for exposing the microwire is facilitated by way of sufficiently bending the glass coated microwire to break the glass coating while maintaining the embedded microwire intact.

### CROSS REFERENCE TO RELATED APPLICATION

This application claims priority to U.S. Provisional Patent Application No. 62/084,577, filed Nov. 26, 2014, entitled “METHOD OF EXPOSING A GLASS-COATED MICROWIRE,” the disclosure of which is incorporated herein by reference in its entirety.

### FIELD OF THE INVENTION

The present invention relates to glass-coated microwires and uses thereof, and in particular to a method for exposing segments of the microwire from its glass coating in a controllable manner, therein enabling its use in electronic circuits, devices and systems.

### BACKGROUND OF THE INVENTION

Glass coating of microwires have been known in the art since as early as 1928, when Taylor was granted U.S. Pat. No. 1,793,529 entitled “Process and apparatus for making filaments”. Applications for microwires include heating elements, infrared (IR) emitters, security tags, and the like.

Industry use of glass-coated microwire has been limited, however, in part due to the difficulties associated with working with glass-coating microwires, primarily due to its delicate nature. In order to employ and/or integrate a microwire in an electrical circuit, the glass coating must be selectively removed about at least at two segments of the glass-coated microwire in order to remove the glass coating and to expose the expose the microwire itself.

Typically, the glass coating is removed manually, for example by striking the microwire gently with a hammer by a skilled worker until a portion of microwire is exposed. Such a process is labor-intensive and prone to human error.

It would therefore prove advantageous to provide a method to efficiently expose portions of a glass-coated microwire and increase industry use thereof.

### SUMMARY OF THE INVENTION

There is an unmet need for, and it would be highly useful to have, a method for selectively and efficiently exposing a microwire filament core along a specific segment and/or portion of a glass coated microwire, without compromising the overall function of a glass coated microwire.

The present invention overcomes these deficiencies of the background by providing a system and method for controllably exposing the microwire from its glass coating therein enabling its integration within electronic circuits, devices and systems, in an efficient manner.

Embodiments of the present invention provide a method for controllably exposing a segment of a glass-coated microwire such that a selected segment of microwire is exposed by way of removing its glass coating. The method comprises controllably bending the glass-coated microwire along a segment to be exposed therein breaking the glass coating only the selected segment to be exposed, this is accomplished while maintaining the underlying microwire intact. The method comprising, determining a first threshold bending radius, respective of the glass coating of the glass-coated microwire and determining a second threshold bending radius, respective of the embedded microwire core. The glass-coated microwire is selectively bent at selected location with a peg and/or apparatus configured to have a radius that is below (smaller) then the glass coating threshold bending radius, so as to break the glass coating at the selected exposure site.

Optionally and preferably bending may be performed around a tool and/or peg having a radius configured to selectively expose the microwire by breaking the surrounding coating only in the vicinity of the peg.

The glass-coated microwire may be bent around a peg having a radius smaller than the glass threshold bending radius. Most preferably during the bending process the microwire core remains intact as the peg's bending radius is selected so as to not affect and/or damage the underlying core microwire filament.

Most preferably, the microwire core portion of the glass coated microwire, has a threshold bending radius that is smaller than that of the glass coating threshold bending radius. Therefore the bending tool and/or peg is utilized to selectively bend the glass-coated microwire along a selected portion of the microwire to exposed the microwire core where the glass coating has broken at the bending position. Preferably the bending radius is selected to be below the glass coating threshold bending radius and above the microwire core bending radius.

In embodiments the exposed segment of the microwire may be coupled to electronic components, circuits, devices and or systems.

In embodiments, the bending peg and/or tool utilized to controllably bend the glass coated microwire may be utilized to facilitate coupling the exposed microwire portion to electronic components, circuits, devices and/or systems. Optionally the bending peg and/or tool may be provided from electromagnetically conducting materials.

Optionally the bending peg and/or tool may be fit with coupling medium, for example including but not limited to soldering materials, so as to allow for timely coupling the exposed microwire portion to electronic components, circuits, devices, and/or systems. Optionally at portion of the bending peg and/or tool may be directly associated with the exposed microwire portion, for example by the application of a coupling medium for example including but not limited to solder that becomes coupled with the application of heat.

Unless otherwise defined, all technical and scientific terms used herein have the same meaning as commonly understood by one of ordinary skill in the art to which this invention belongs. The materials, methods, and examples provided herein are illustrative only and not intended to be limiting. Implementation of the method and system of the present invention involves performing or completing certain selected tasks or steps manually, automatically, or a combination thereof.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in order to provide what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the drawings:

FIG. 1 is a schematic block illustrative diagram of a glass coated microwire that may be bent according embodiments of the present invention;

FIG. 2 is a schematic flowchart of a method for controllably exposing a portion of a microwire according to embodiments of the present invention;

FIG. 3A-B are a schematic illustrative diagram of an exemplary a glass coated microwire that are bent according to embodiments of the present invention; and

FIG. 4 is a schematic illustrative diagram of an exemplary glass coated microwire that is bent according to embodiments of the present invention;

### DESCRIPTION OF THE PREFERRED EMBODIMENTS

The principles and operation of the present invention may be better understood with reference to the drawings and the accompanying description. The following figure reference labels are used throughout the description to refer to similarly functioning components are used throughout the specification hereinbelow.

100, 200, 400 glass coated microwire;

110 glass coating;

110a,b glass coating portions;

120 microwire core;

125 exposed microwire portion;

130 bend radius;

132 glass coating threshold bending radius/first threshold radius;

134 microwire core threshold bending radius/second threshold radius;

140 bending apparatus/peg;

142 bending radius;

150 bending region;

410,420 bending peg arrangement;

430 bending peg stage/base;

450 exposed microwire portions;

500 electronics

An apparatus includes a glass coated microwire, wherein the microwire is exposed. The method for exposing a glass-coated microwire includes determining a first bend radius, respective of the glass coat of the glass-coated microwire. The glass-coated microwire is bent at a radius below the glass coat first bend radius, so as to break the glass coat. The glass-coated microwire may be bent around a peg. The peg may have a radius smaller than the first bend radius. The microwire remains intact, as it has a second bend radius, smaller than that of the first bend radius. Thus, a portion of the microwire is exposed where the glass coat has broken at the bend. In certain embodiments, the peg may include soldering material. Thus, after the microwire is exposed, heat may be applied to solder the exposed microwire and the peg together.

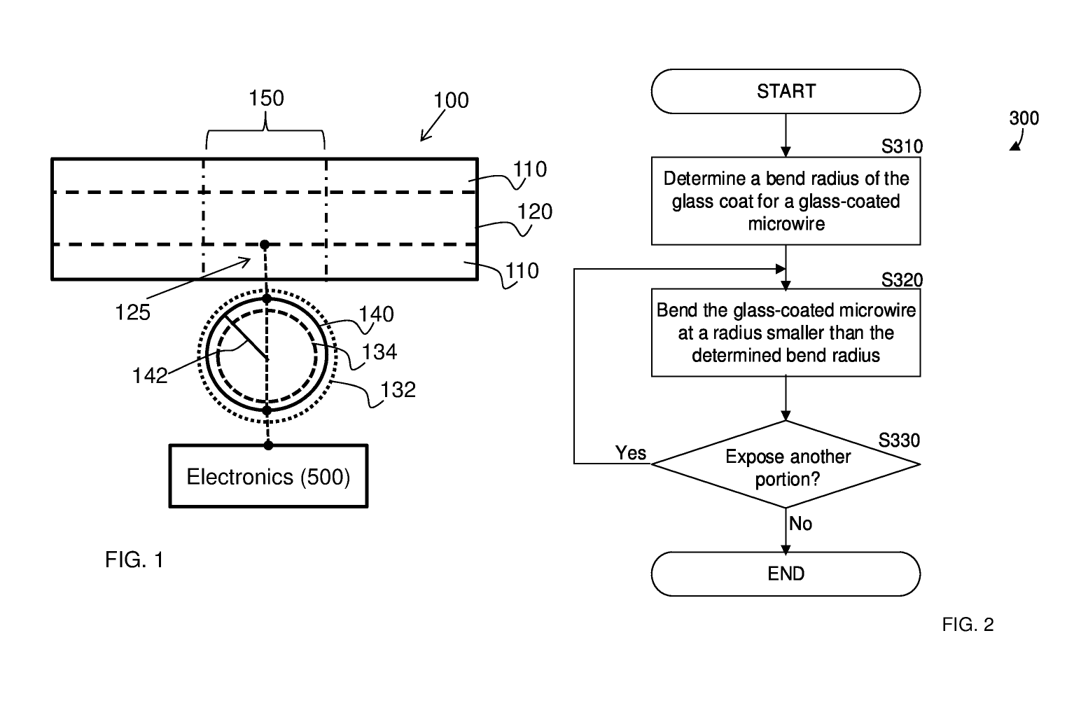

Now referring to FIG. 1 showing a schematic block diagram of a glass coated microwire 100 having a glass coating 110 around a microwire core 120. The glass coated microwire 100 may be selectively bent around a given bending zone and/or area 150 so as to selectively and safely break the glass coating 110 in the bending zone 150 and to expose the microwire core 120, forming an exposed microwire portion 125.

Most preferably exposed microwire core 125 may then be functionally coupled to electronics 500. Electronics 500 may be realized in optional forms for example including but not limited to electronic components, circuits, devices and/or systems, the like, or any combination thereof.

Most preferably glass coated microwire 100 is bent about a bending apparatus and/or tool 140 having a bending radius 142. Bending apparatus 140 and/or tool may for example be provided in the form of a peg, for example as shown.

Most preferably the bending apparatus 140 and in particular the bending radius 142 is configured according to at least one parameter and/or property of the glass coated microwire 100. Preferably the glass coated microwire parameter utilized to determine the bending radius 142 is the threshold bending radius 132 of the glass coating 110. Preferably bending radius 142 is selected to be smaller than the threshold bending radius 132 associated with the glass coating 110 of the glass coated microwire 100.

Optionally a second glass-coated microwire 100 parameter is utilized to determine bending radius 142. Preferably the second parameter utilized is the threshold bending radius 134 associated with the microwire core 120. Optionally the bending radius 142 is selected based on at least two glass coated microwire 100 parameters comprising the glass coating (110) threshold bending radius 132 and the microwire core (120) threshold bending radius 134. Optionally the bending radius 142 may therefore be selected so as to be smaller than glass coating (110) threshold bending radius 132 and larger than the microwire core (120) threshold bending radius 134. Utilizing both parameters provides for selectively and controllably breaking glass coating 110 at bending region 150 to safely expose microwire core 120 at microwire core exposure point 125 without compromising the functionally of the microwire core 120.

Once exposure point 125 is generated according to the method of the present invention glass coated microwire 100 may be functionally coupled to electronics 500 for example by way of soldering, or the like electronic coupling techniques.

The threshold bending radius is a measure of the inside curvature of the minimum radius that a pipe, tube, sheet, cable, hose and the like can be bent without breaking. The smaller the bending radius, the greater the material flexibility. Accordingly the threshold bending radius may be individually determined for the glass coating 110, microwire core 120 and the glass coated microwire 100. Optionally each of these parameter may be utilized to determine the bending radius 142 that may be utilized with a particular glass-coated microwire 100.

Microwire core 120 may be an amorphous metal, also known as metallic glass. Glass coating 110 may be a composite material of and is typically a borosilicate composite, however may be provided in optional forms.

Core microwire 120 has a different threshold bending radius 134 that is smaller than the glass coating threshold bending radius 132. Accordingly, the glass-coated microwire 100 may be bent at a radius smaller than the glass coating threshold radius 132 of the glass coat 110 but larger than the microwire core threshold bending radius 134 of microwire core 120, it is possible to expose a portion 125 of the microwire core 120 at a controllable bending region 150, without damaging the glass coat 110 in other portions of microwire 100.

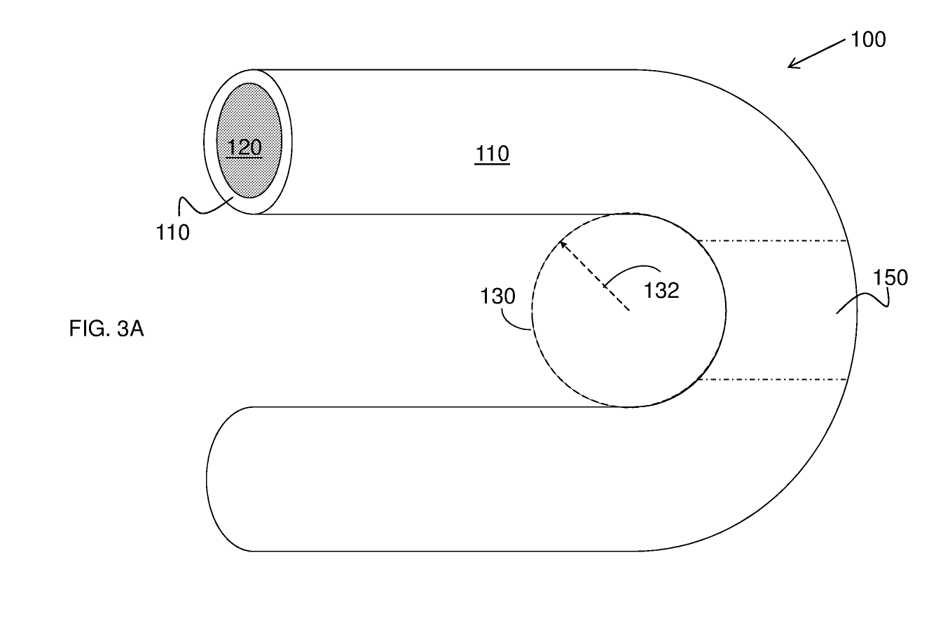

FIG. 2 is a non-limiting exemplary flowchart 300 of a method for exposing a portion 125 of microwire core 120 of a glass-coated microwire 100 at a bending region 150 according to an embodiment of the present invention. First in stage S310 a first threshold bend radius 132, respective of the glass coat of a glass-coated microwire is determined. The bend radius is a measure of the inside curvature of the minimum radius that a pipe, tube, sheet, cable, hose and the like can be bent without breaking. The smaller the bending radius, the greater the material flexibility. For example, for a five millimeter glass-coated microwire 100, the bend radius may be fifty-five micrometers. Typically, the bend radius of the glass coating 110 is higher than the bend radius of the microwire core 120. In an optional embodiment, a second threshold bend radius 134 may be determined respective of the microwire core 120.

Next in stage S320 the glass-coated microwire 100 is bent at a radius 142 that is configured to be smaller than the first threshold bend radius 132 of the glass coating 110, so as to break the glass coating 110 in the bending region 150. The microwire core 120 remains intact, as it has a second threshold bending radius 134, that is most preferably smaller than that of the first threshold bend radius 132 of the glass coating 110. Thus, a portion of the microwire core 120 is exposed 125 where the glass coating has broken, along the bending portion 150.

Next in stage S330 a check is performed to determine if the glass-coated microwire 100 should exposed at additional portions 150. If so, execution continues at stage S320, otherwise execution ends.

In some embodiments, the glass-coated microwire 100 may be bent with a bending device and/or apparatus 140, for example a solid peg 140 as shown. Bending apparatus and/or peg 140 is configured to have a radius 142 that is smaller than the first threshold bend radius 132 of the glass coat 110, but larger than the second threshold bend radius 134 of the metallic microwire core 120.

In some embodiments, the bending apparatus 140 for example in the form of a peg may have a cross-section of any geometric shape for example including but not limited to a circle, a polygon, a polygon of n sides wherein n is bigger than three, the like or any combination thereof.

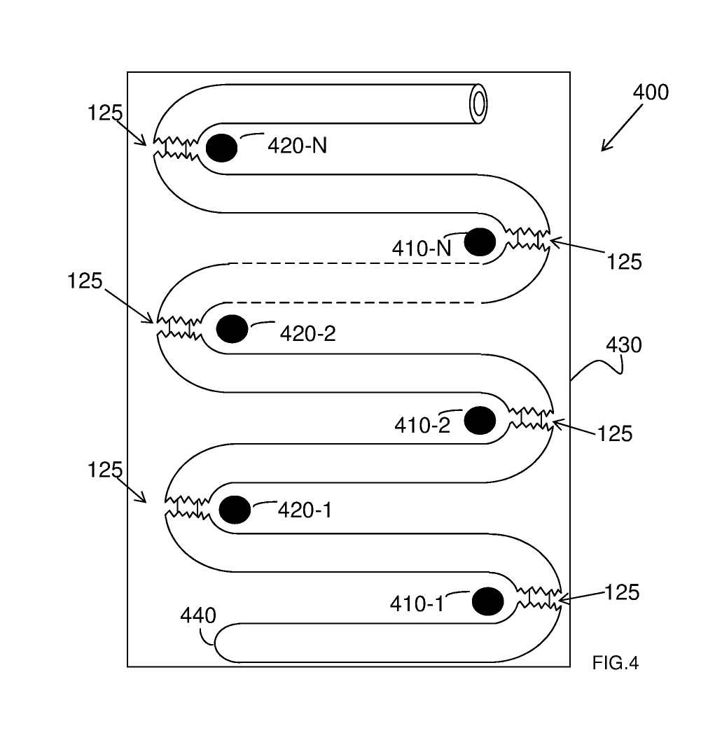

In certain embodiments, the bending apparatus and/or device 140, for example in the form of a peg, may include an electronic coupling medium, for example including but not limited to a soldering coat and/or deposit so as to facilitate coupling the exposed microwire portion 125 to electronics 500. For example, after microwire 100 is exposed at point 125 along segment 150, heat may be applied to solder the exposed microwire 125 and the peg 140 together. Optionally thereafter peg 140 may be coupled to electronics 500 for example including but not limited to components, circuits, devices, systems, the like or any combination thereof. Optionally a network of bending pegs 140 may be distributed on a stage and/or base to allow bending and coupling the glass-coated microwire 100 to option electronic units 500, for example a will be described in greater detail in FIG. 4.

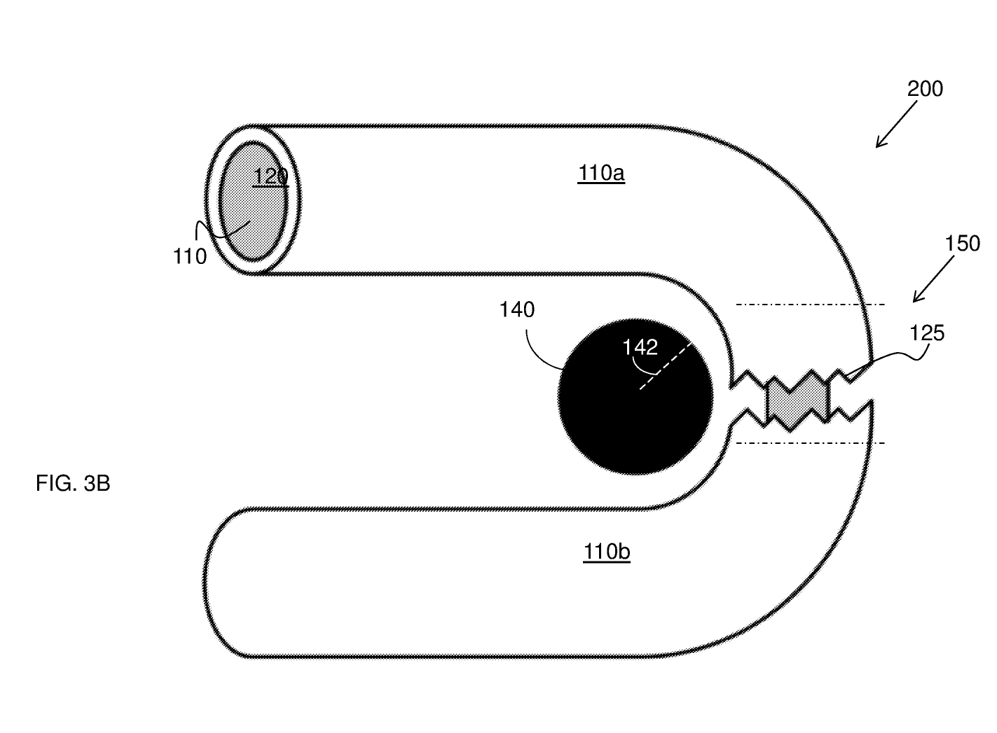

FIG. 3A-B show schematic illustration of glass coated microwire 100 that may be bent according to embodiments of the present invention. FIG. 3A provides an illustrative depiction of the glass coated microwire depicted in FIG. 1. FIG. 3A further shows microwire core 120 having a glass coating 110, that is to be bent over a region 150 to expose the microwire core preferably for coupling to electronics 500. Glass coating 110 of the has a first threshold bending radius 132 corresponding to the radius of circle 130. The microwire core 120 may be an amorphous metal, also known as metallic glass. The glass coating 110 is typically a borosilicate composite. The microwire 120 has a second bend radius, which is smaller than the first bend radius of the glass coat. Thus, if the glass-coated microwire is bent at a radius smaller than the first radius of the glass coat 110 but larger than the second bend radius of the microwire120, it is possible to expose a portion of the microwire 120 at the bend point, without damaging the glass coat 110 in other portions.

FIG.3B shows a non-limiting exemplary schematic illustration of an exposed a glass-coated microwire 200 with exposed portion 125 along segment 150 that was exposed according to the method of the present invention. The glass coated microwire is bent around a peg 140. Peg 140 having a radius 142 configured according to at least a first parameter, glass coating threshold bending radius 132 and optionally according to an additional second parameter, microwire core threshold bending radius 134. Preferably radius 142 is therefore configured to be smaller than the first threshold bend radius 132 of the glass coat 110 but larger than the second threshold bending radius 134 of the microwire core 120. By bending around peg 140 having radius 142 the glass coating 110 is broken at bending segment 150 into a first portion 110a and a second portion 110b, exposing a portion 125 of microwire core therebetween.

FIG. 4 is a non-limiting exemplary schematic illustration of a glass-coated microwire 100, for example in the form of an emitter 400. Optionally emitter 400 includes a first plurality of pegs 410-1 through 410-N and a second plurality of pegs 420-1 through 420-N, all arranged on a stage and/or base 430, where N is a natural number greater than 1.

In this exemplary illustration showing how the method of the present invention may be utilized to couple a glass coated microwire 100, 200 to optional electronic units 500. Stage 430 includes first pegs 410 and second pegs 420 that are arranged in a pattern corresponding to antinodes of a wave.

In other embodiments, bending pegs 140 may be arranged along a stage 430, in any manner such that the first plurality of pegs 410 is positioned across from the second plurality of pegs. A glass-coated microwire 440, 100 is wound around the system of peg 410,420, such that the glass-coated microwire 440, 100 is wound from right to left on peg 410-1, then left to right on peg 420-1, then right to left one peg 410-2 and so on. The radius 142 of pegs 410 and pegs 420 are configured to be smaller than the first threshold bending radius 132 of the glass coat 110, but larger than the second threshold bending radius 134, of the microwire core 120, such that when the glass-coated microwire 440,100 is bent on each peg, the glass coating 110 selectively breaks at bending region 150 to exposing a portion 125 of the microwire core 120. The exposed microwire core portions 125 may then by soldered and/or otherwise functionally coupled to the bending pegs 410-1 and 420-1, and thereafter may further connect and/or functionally couple pegs 410-1 and 420-1 to an optional electronics unit 500, for example in the form of a circuit (not shown). Optionally electronics 500 may for example include a power source, that may for example provide for producing various device incorporating the microwire for example including but not limited to an emitter. For example, the glass coat 110 may be a borosilicate composition, which has a refractive index allowing infrared (IR) radiation to pass through. Thus, a glass-coated microwire connected to a power source may be used as an IR emitter. A plurality of glass-coated microwire portions may be created between each set of pegs 410-i and 420-i, where i is a natural number from 1 to N. Each glass-coated microwire portion produced may be further connected to a circuit.

All examples and conditional language recited herein are intended for pedagogical purposes to aid the reader in understanding the principles disclosed herein and the concepts contributed by the inventor to furthering the art, and are to be construed as being without limitation to such specifically recited examples and conditions. Moreover, all statements herein reciting principles, aspects, and embodiments, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

While the invention has been described with respect to a limited number of embodiment, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not described to limit the invention to the exact construction and operation shown and described and accordingly, all suitable modifications and equivalents may be resorted to, falling within the scope of the invention.

Having described a specific preferred embodiment of the invention with reference to the accompanying drawings, it will be appreciated that the present invention is not limited to that precise embodiment and that various changes and modifications can be effected therein by one of ordinary skill in the art without departing from the scope or spirit of the invention defined by the appended claims.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub-combination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the scope of the appended claims.

Citation or identification of any reference in this application shall not be construed as an admission that such reference is available as prior art to the invention.

Section headings are used herein to ease understanding of the specification and should not be construed as necessarily limiting.

While the invention has been described with respect to a limited number of embodiments, it will be appreciated that many variations, modifications and other applications of the invention may be made.

1-11. (canceled)

12. A method for exposing at least a portion of a microwire core of a glass-coated microwire, the method comprising:
a. determining a first threshold bending radius, respective of the glass coating of the glass-coated microwire;
b. determining a second threshold bending radius, respective of the microwire core of the glass-coated microwire; wherein bending at a curvature radius configured to be smaller than the first threshold radius and larger than the second threshold radius; and
c. bending the glass-coated microwire along a portion thereof about a bending apparatus or a peg, at said curvature radius.

13. The method of claim 12 further comprising functionally coupling said bending peg to the exposed microwire.

14. The method of claim 12, wherein the cross section of the bending apparatus or peg is one of: a circle, a polygon, a polygon of n sides wherein n>3.

15. The method of claim 12, wherein the peg further comprises electronic coupling medium or soldering material.

16. The method of claim 15, further comprising: applying heat to the peg, so that the soldering material fuses the peg and the at least a portion of exposed microwire.

17. The method of claim 15, further comprising: applying heat to the peg, so that the soldering material fuses the peg, at least a portion of exposed microwire, and an electronics unit selected from electronic components, electronic devices, electronic circuits, electronic systems, or any combination thereof.

18. The method of claim 12 wherein said microwire is bent at a plurality of bending locations along said glass-coated microwire with at least one bending peg and wherein each bend is provided at said curvature radius.

19. The method of claim 12 wherein said microwire is bent at a plurality of bending locations along said glass-coated microwire with a plurality of bending pegs with a plurality of bending pegs wherein each bend is provided at said curvature radius.

20. An apparatus, comprising:
a. a base onto which a glass-coated microwire is affixed;
b. said base featuring at least one peg; for bending said coated microwire; wherein said glass-coated microwire is bent at least once at a radius about said at least one peg, wherein said radius is configured to be smaller than a first threshold bending radius, respective of the glass coating of the glass-coated microwire, and larger than a second threshold radius respective of the microwire's core, such that when bent at said radius at least a portion of the microwire core is at least partially exposed at a bending site. The apparatus of claim 8, wherein the glass coated microwire is bent at least twice at said radius further comprising:
c. a circuit, the circuit connected to the microwire at least at the first bend and the second bend.

21. The apparatus of claim 20, wherein the circuit further comprises a power source, and the circuit is operative to apply a voltage through the microwire, causing the microwire to emit at least infrared (IR) radiation.

22. The apparatus of claim 20 further comprising a microwire coupling medium for coupling the microwire to electronics.

23. The apparatus of claim 22 wherein said coupling medium is solder.

24. The apparatus of claim 22 wherein said coupling medium is heat sensitive material.

25. The apparatus of claim 20 wherein said stage comprises a plurality of bending pegs.

26. The apparatus of claim 20 wherein said peg is configured to have a radius that is smaller than said first threshold bending radius and larger than said second threshold bending radius.

27. The apparatus of claim 20 wherein said peg includes electronic coupling medium.

28. The apparatus of claim 20 wherein said peg has a cross sectional shape of any geometric shape selected from a circle, a polygon, a polygon of n sides wherein n>3.

29. The apparatus of claim 20 wherein said peg is provided from conducting materials.

30. A glass coated microwire apparatus provided in the form of an IR emitter including:
a. a glass coated microwire having a microwire core and a glass coating wherein said glass coating is a borosilicate composition having a refractive index allowing infrared (IR) radiation to pass therethrough; wherein said microwire is bent at least once forming at least one bending site wherein at least a portion of the microwire core is at least partially exposed; said at least one bending site having a radius that is smaller than a first threshold bending radius , respective of the glass coating , and larger than a second threshold radius , respective of the microwire's core;
b. a peg provided from conducting materials that is coupled to said microwire at said exposed portion; and wherein said peg is further coupled to a power source.

31. The apparatus of claim 30 further comprising electronic circuitry that is coupled to at least one of said peg or said power source.
